(19) United States
(12) Patent Application Publication
(10) Pub. No.: US 2008/0131048 A1
(43) Pub. Date: Jun. 5, 2008

(54) Optical Fibre Switch

(75) Inventors: Ju Hyun Yoo, Auckland (NZ); Wei Gao, Auckland (NZ)

Correspondence Address: FULBRIGHT & JAWORSKI L.L.P, 2200 ROSS AVENUE, SUITE 2800, DALLAS, TX, 75201-2784, US

(73) Assignee: Auckland UniServices Limited, Auckland (NZ)

(21) Appl. No.: 11/574,186

(22) PCT Filed: Aug. 22, 2005
(86) PCT No.: PCT/NZ05/00216

§ 371 Date: Sep. 12, 2007

(30) Foreign Application Priority Data
Aug. 24, 2004 (NZ) 534883

(51) Int. Cl. G02B 6/35; H01L 41/09; H01L 41/187

(52) U.S. Cl. 385/6; 385/8; 310/358; 310/330

(57) ABSTRACT

An optical fibre switch (10) includes an optical fibre conduit (12). A transducer (16) is carried on the conduit (12), the transducer (16) converting input energy of one form into mechanical energy so that the application of an external stimulus causes a change in condition of the transducer (16) which imparts that change in condition to the conduit (12). An input energy applying arrangement (20) is arranged on the transducer (16) for applying the external stimulus.

### CROSS-REFERENCE TO RELATED APPLICATIONS

The present application claims priority from New Zealand Provisional Patent Application No 534883 filed on 24 Aug. 2004, the contents of which are incorporated herein by reference.

### FIELD OF THE INVENTION

This invention relates to switching. More particularly, the invention relates to switching in optical fibres and, more specifically, to an optical fibre switch.

### BACKGROUND TO THE INVENTION

Optical fibre signal transmission has become a critical part of the telecommunications industry, particularly in areas where signals may be susceptible to noise. During signal transmission, it may be necessary for the optical beam to be switched between a number of optical fibres in a transmission path. Optical fibre switching involves mechanically operated systems using mirrors to reflect light and, in so doing, change the light paths. These are complex systems and, due to the fact that mechanically moving parts are used, switching action is slow and the systems are susceptible to failures.

### SUMMARY OF THE INVENTION

According to the invention, there is provided an optical fibre switch which includes:

an optical fibre conduit;

a transducer carried on the conduit, the transducer converting input energy of one form into mechanical energy so that the application of an external stimulus causes a change in condition of the transducer which imparts that change in condition to the conduit; and

an input energy applying arrangement arranged on the transducer for applying the external stimulus.

The optical fibre conduit may be a single optical fibre. In other words, the optical fibre conduit may have a single conduit for guiding a light beam. Instead, the optical fibre conduit may be a conduit containing a bundle of optical fibres.

The transducer may convert input electrical energy into mechanical energy. More particularly, the transducer may be of the type comprising dielectric materials that undergo mechanical deformation upon the application of a voltage to the material.

The transducer may be a sleeve, formed as a tube or a coating, of a piezoelectric material which, when the external stimulus is applied to the sleeve, causes a change in the mechanical condition of the sleeve. More particularly, the application of the voltage may cause the sleeve to bend to enable controlled switching to be effected.

The input energy applying arrangement may be in the form of an electrode assembly carried on an external surface of the sleeve. The electrode assembly may comprise at least two pairs of opposed electrodes arranged on the sleeve for effecting bending of the sleeve in the desired direction. The electrode assembly may further include a ground electrode arranged on an operatively inner surface of the sleeve of piezoelectric material. It will be appreciated that, by appropriate application of voltage to the pairs of electrodes, the sleeve, with the conduit therein, can be made to deflect or bend omnidirectionally.

The piezoelectric material may be a piezoelectric ceramic material having a high electromechanical coupling coefficient. Preferably, the piezoelectric ceramic material is lead zirconate titanate (PZT) with or without doping.

The sleeve may be formed by a deposition technique. More particularly, the sleeve may be formed by an electrophoretic deposition technique on a former, the former subsequently being removed. For example, PZT particles may be charged in suspension to be deposited on a graphite former functioning as a cathode. A stainless steel container in which the former is arranged may act as the anode. After deposition of the PZT particles on the former, the former may be burnt out in a furnace to leave the PZT tube. Electrodes may then be applied to the tube to form the sleeve.

The switch may include a housing in which the transducer and its associated optical fibre conduit are arranged. A combination of the transducer with the optical fibre conduit therein may be mounted in a cantilevered arrangement in the housing.

The switch may include a latching arrangement for latching at least the optical fibre conduit in a desired position in the housing. The latching arrangement may comprise a latching element carried proximate a free end of the cantilevered combination and at least one retaining member arranged in the housing to hold at least the optical fibre conduit in its switched position. The switch may comprise as many retaining members as there are switched positions to which the cantilevered combination is to be switched.

The at least one retaining member may be a magnetic device and the latching element may comprise a magnetically responsive element carried by the cantilevered arrangement.

The transducer may be a snug fit over the optical fibre conduit. Instead, the transducer may be a rattling fit over the optical fibre conduit.

The latching arrangement may be used where the transducer is a rattling fit over the optical fibre conduit so that, when the transducer has been deflected to the desired position by the application of electrical energy, the optical fibre conduit is retained in that position. The application of energy to the transducer is then discontinued to allow the transducer to return to its rest position in the housing.

According to a second aspect of the invention, there is provided a switch transducer which includes

a sleeve of a piezoelectric material; and

an input energy applying arrangement arranged on the sleeve for applying an external stimulus to the sleeve.

The piezoelectric material may be a piezoelectric ceramic material having a high electromechanical coupling coefficient. Preferably, the piezoelectric ceramic material is lead zirconate titanate (PZT) with or without doping.

The sleeve may be formed by a deposition technique. More particularly, the sleeve may be formed by an electrophoretic deposition technique on a former, the former subsequently being removed.

The input energy applying arrangement may be in the form of an electrode assembly carried on an external surface of the sleeve. The electrode assembly may comprise at least two pairs of opposed electrodes arranged on the sleeve for effecting bending of the sleeve in the desired direction. The electrode assembly may further include a ground electrode arranged on an operatively inner surface of the sleeve of piezoelectric material.

### BRIEF DESCRIPTION OF THE DRAWINGS

Embodiments of the invention are now described, by way of example, with reference to the accompanying diagrammatic drawings in which:

FIG. 1 shows a schematic end view of an optical fibre switch, in accordance with a first embodiment of one aspect of the invention;

FIG. 2 shows a schematic end view of another embodiment of the optical fibre switch;

FIG. 3 shows a schematic side view of the optical fibre switch of FIG. 2;

FIG. 4 shows a schematic representation of the optical fibre switch of FIGS. 2 and 3, in use;

FIG. 5 shows a side view of a further embodiment of the optical fibre switch;

FIG. 6 shows a side view of yet another embodiment of the optical fibre switch;

FIG. 7 shows an end view of a switch transducer in accordance with an embodiment of another aspect of the invention;

FIG. 8 shows a graph of deflection of a switch transducer v wall thickness; and

FIG. 9 shows a series of representations of the operation of yet a further embodiment of the optical fibre switch.

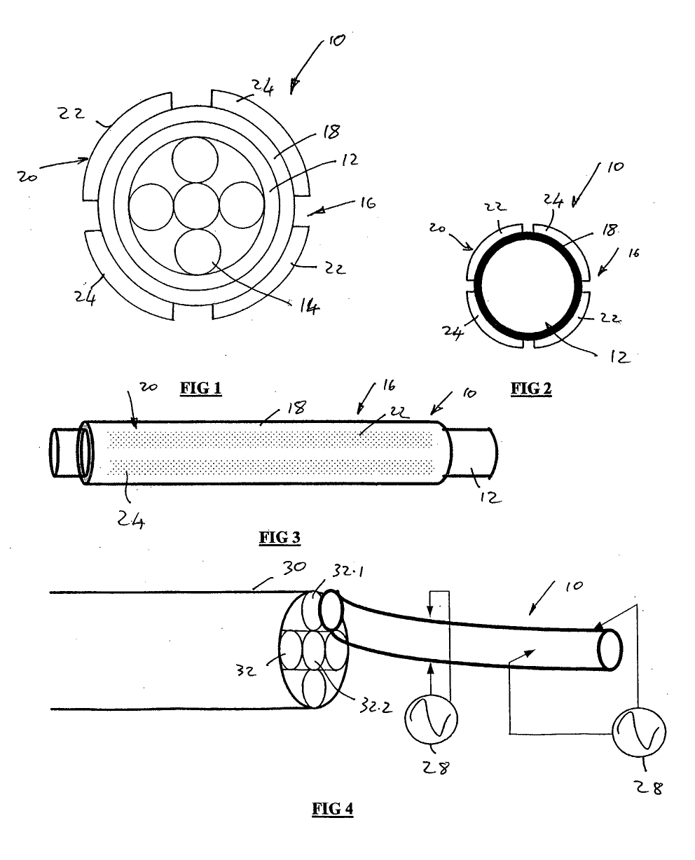

### DETAILED DESCRIPTION OF THE EXEMPLARY EMBODIMENTS

In the drawings, reference number 10 generally designates an optical fibre switch, in accordance with embodiments of the invention.

The switch 10 includes an optical fibre conduit 12. In the embodiment of the invention illustrated in FIG. 1 of the drawings, the conduit 12 surrounds a bundle of optical fibres 14. In the embodiment of the invention illustrated in FIG. 2 of the drawings, the optical fibre conduit 12 is a single optical fibre conduit.

A transducer 16 is carried on the conduit 12, the transducer 16 converting input electrical energy into mechanical energy. More particularly, the transducer comprises a sleeve 18 of piezoelectric material applied to the conduit 12. The sleeve 18 of the transducer 16 is applied by way of applying a coating of the material on to an external surface of the conduit 12. Instead, the sleeve 18 of the transducer 16 is applied by way of a tube of, or containing, piezoelectric material, the tube being placed about the conduit 12.

The transducer 16 can be applied to conduits 12 ranging in size from 0.1 millimetres to a number of centimetres in diameter, i.e. in the range of a single fibre 14 to a large bundle of optical fibres 14. In addition, micro-sized transducers 16 can also be fabricated. The transducer 16, as applied to the conduit 12, is heat treated to achieve the desired phase and microstructure and to ensure that the transducer 16 has the required dielectric and piezoelectric properties.

The material of the sleeve 18 is, preferably, a piezoelectric ceramic material of the general formula Pb(Zr,Ti)O₃ and is mainly of the form Pb(Zr₁₋ₓ, Tiₓ,)O₃+doping additives. It will be appreciated that the proportion of Pb and Ti can be changed to impart different characteristics to the coating. Another way to modify the properties of the coating is to dope the material with Lanthanum to form (Pb,La)(Zr,Ti)O₃. Other doping elements that could be used to modify the properties of the material include Nb, Sb, Fe, Ta, Cr, Co, Mn and rare-earth elements. Yet other materials which may be used for the sleeve 18 include Pb(Zn₁₋ₓ, Nbₓ,)O₃ and Pb(Sc₁₋ₓ,Nbₓ)O₃-PbTiO₃ compounds. In a preferred implementation, a piezoelectric ceramic material of the sleeve 18 is lead zirconate titanate (PZT).

It is to be noted that, in the embodiment of FIG. 1 of the drawings, the transducer 16 surrounds the bundle of fibres 14. In other words, the transducer 16 is arranged externally of the enveloping conduit 12. In the embodiment of the invention illustrated in FIG. 2 of the drawings, the transducer 16 is applied to the external surface of the single optical fibre conduit 12.

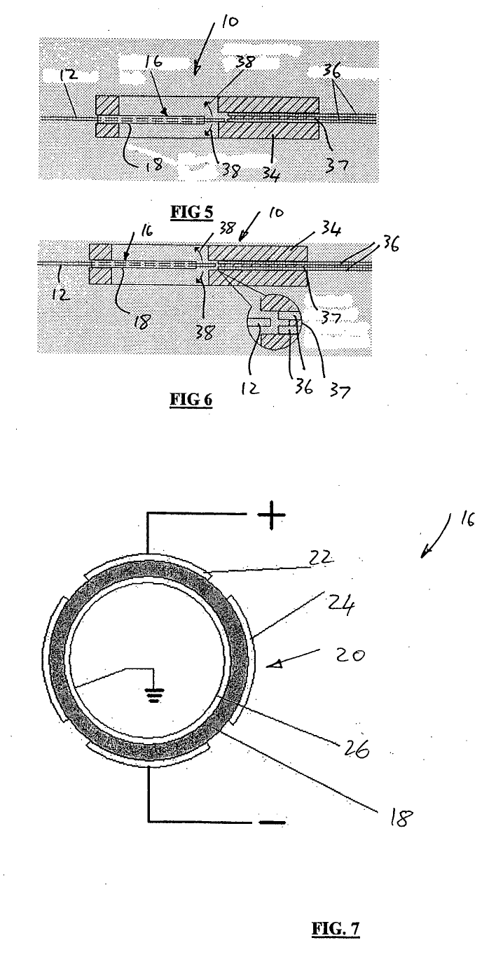

The switch 10 further includes an input energy applying arrangement 20. The input energy applying arrangement 20 comprises a first pair of opposed electrodes 22 and a second pair of opposed electrodes 24. The electrodes 24 are orthogonally arranged with respect to the pair of electrodes 22. A ground electrode 26 (FIG. 7) is arranged on an operatively inner surface of the sleeve 18.

A switch transducer 16 is illustrated in FIG. 7 of the drawings. The transducer 16 comprises the sleeve 18 of the piezoelectric material with the electrodes 20, 24 and 26 applied to the sleeve 18.

As shown schematically in FIG. 4 of the drawings, each pair of electrodes 22, 24 has a power supply, such as a voltage generator, 28 associated with it.

In the case of the embodiment shown in FIG. 1, and as shown schematically in FIG. 4 of the drawings, a switch 10 is placed at the end of an optical fibre bundle 30 having a plurality of optical fibres 32. Another bundle (not shown but referred to below for ease of reference as the “downstream bundle”) of optical fibres is arranged at an opposed end of the switch 10. In other words, the switch 10 is interposed between aligned ends of the bundle 30 and the downstream bundle.

As an example, should it be desired to switch a light beam exiting an optical fibre 32.1 of the bundle 30 into an optical fibre of the downstream bundle aligned with the optical fibre 32.2 of the bundle 30, an appropriate voltage is applied to the pairs of electrodes 22 and 24 of the switch 10, via the power supplies 28, to cause the switch 10 to bend to the position as shown in FIG. 4 of the drawings. As a result, a light beam exiting the optical fibre 32.1 is directed, via the switch 10, into the optical fibre of the downstream bundle aligned with the optical fibre 32.2 of the bundle 30.

It will be appreciated that, by appropriate application of a voltage to the electrodes 22, 24 via the power supplies 28, the sleeve 18 of the transducer 16 of the switch 10 is made to bend in any desired direction in a fast and accurate manner. Hence, rapid switching in an optical fibre network can be achieved. Further, it will be appreciated that, if the bundle 30 and/or the downstream bundle carries the transducer 16 directly, the bundles themselves can be made to bend in the desired direction by the appropriate application of voltage to the electrodes 22, 24 of the bundles. This will achieve the same switching result and the need for the switch interposed between the bundles may be obviated.

FIGS. 5 and 6 show a further embodiment of the optical fibre switch 10. With reference to the previous drawings, like reference numerals refer to like parts unless otherwise specified. In this embodiment the switch 10 includes a housing 34. The transducer 16, with a single optical fibre conduit, or input optical fibre, 12 (for example, as shown in FIG. 2 of the drawings) is arranged within the housing 34. The transducer 16 is arranged in a cantilevered fashion in the housing 34. A pair of output optical fibres 36, in respect of which switching is to occur, extends from the housing 34. The optical fibres 36 are of the same diameter as the optical fibre conduit 12 and are separated by a spacer 37.

Due to the cantilevered mounting of the transducer 16 within the housing 34, on the application of a voltage from the power supplies 28 to the electrodes 22, 24, the sleeve 18 of the transducer 16 can bend in the direction of arrows 38.

In the embodiment shown in FIG. 5 of the drawings, when the transducer 16 is in a rest condition, i.e. where no voltage is applied to its electrodes 22, 24, the input optical fibre 12 is aligned with one of the output optical fibres 36.

In the embodiment shown in FIG. 6 of the drawings, when the transducer 16 is in its rest condition, the input optical fibre 12 is aligned with the spacer 37 between the output optical fibres 36.

In the case of the embodiment shown in FIG. 5 of the drawings, the deflection of the tube of the sleeve 18 of the transducer 16 needs to be at least the diameter of the optical fibres 12, 36, for example, 125 μm in order to perform switching from one output optical fibre 36 to the other. The benefit of this arrangement is that, in the rest condition, a light path is still formed between the input optical fibre 12 and that output optical fibre 36 in alignment with the input optical fibre 12 when the transducer 16 is in its rest condition.

In the embodiment illustrated in FIG. 6 of the drawings, the transducer 16 need only deflect the radius of an optical fibre to create a light path between the input optical fibre 12 and the desired output optical fibre 36. However, in this embodiment, when the transducer 16 is in a quiescent, non-active condition, the input optical fibre 12 is not in alignment with either of the output optical fibres 36.

In this embodiment, the spacer 37 may be of the order of 20 μm to achieve isolation between the input optical fibre 12 and the output optical fibres 36 when the transducer 16 is in its rest condition.

The deflection of the transducer 16 is calculated using equation (1) below.

$$ζ = \frac{2 \sqrt{2} {d}_{31} {L}^{2} V}{π D T} \qquad ( 1 )$$

where;
ζ is the deflection of the sleeve 18,
d₃₁is the piezoelectric constant,

### V is the applied voltage,

### L is the length of the sleeve 18,

### D is the inner diameter of the sleeve 18, and

### T is the thickness of the sleeve 18.

The voltage V is fixed at 200V and the length of the sleeve 18 is assumed to be 1 cm. The piezoelectric constant is 150×10⁻¹²m/V.

A graph of deflections of piezoelectric sleeves 18 against wall thickness is set out in FIG. 8 of the drawings.

The dimensions of the sleeve 18 are determined by three factors, the length L, the inner diameter D and the wall thickness T. Increasing the length of the sleeve 18 has the greatest effect on improving its deflection since, from equation (1) it will be noted that deflection is proportional to the square of the length.

FIG. 8 shows that, at the same wall thickness, a sleeve 18 with a smaller inner diameter has a greater deflection. Therefore it is preferable to decrease the inner diameter of the tube. The outer diameter of a standard, single-mode or multi-mode optical fibre is 125 μm. To avoid reducing the thickness of the input optical fibre, the inner diameter of the piezoelectric tube should be made just greater than 125 μm in order to achieve maximum deflection.

Also from equation (1) above and the graph shown in FIG. 8, it will be noted that the thinner the wall of the sleeve 18, the greater the deflection. Thus, the sleeve 18 should be made as thin as the EPD technique, described below, allows.

Referring again to FIG. 5, the deflection of the sleeve 18 must be at least the diameter of an optical fibre 12 which is 125 μm. In this case, a sleeve 18 with an inner diameter of 130 μm will need to have a wall thickness of less than 170 μm. A sleeve 18 with a larger inner diameter will need to have a thinner wall in order to achieve the same deflection.

For the embodiment shown in FIG. 6 of the drawings, the deflection of the sleeve 18 will be at least the radius of an optical fibre 12 which is 65 μm. It is possible therefore to use a thicker tube in this case. For example, a tube having an inner diameter of 130 μm can have a wall thickness of up to 330 μm.

Using electrophoretic deposition (EPD) techniques, sleeves 18 of the required dimensions can be formed. The fabrication of sleeves 18 by EPD consists of four main steps. A powder of PZT is prepared and individual particles are charged in suspension in s suitable organic liquid. A graphite rod is used as a cathode and a stainless steel container, in which the rod is placed, is used as an anode. A voltage of up to 1000 V is applied between the cathode and the anode to cause deposition of the PZT particles on to the graphite rod. The graphite rod is subsequently burnt out in a furnace following which the “green” tubes are sintered. The electrodes 22, 26 and the ground electrode 24 are applied using silver paint.

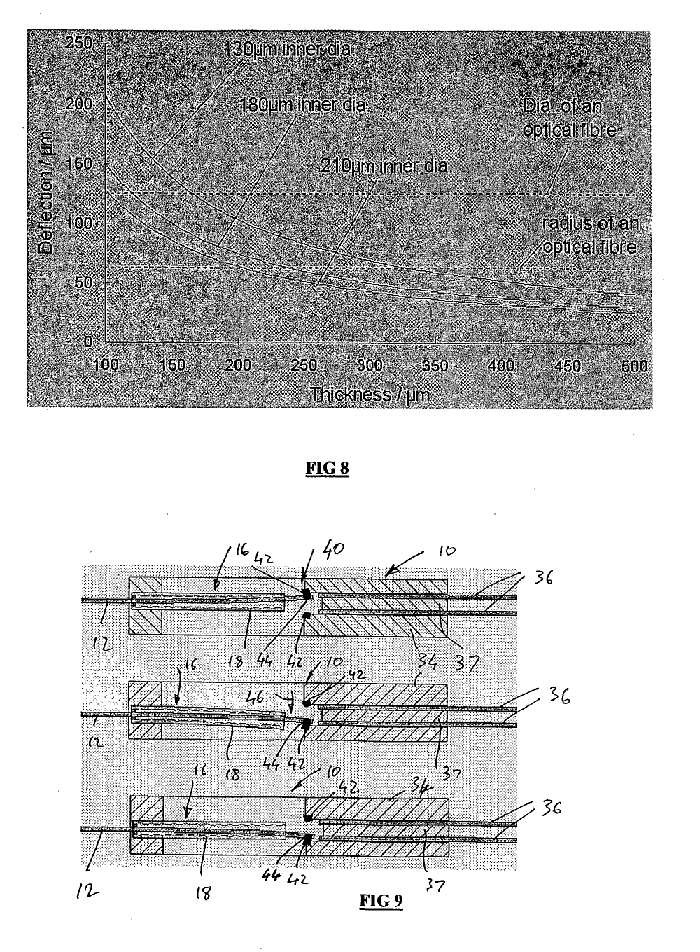

In the embodiments described above, the sleeve 18 is a snug fit on the optical fibre conduit 12. FIG. 9 shows another embodiment of the invention in which the sleeve 18 of the transducer 16 is a rattling fit over the optical fibre conduit 12. By “rattling fit” is meant that the optical fibre conduit 12 can move laterally within the sleeve 18 without the sleeve 18 moving. In this embodiment, the optical fibre switch 10 includes a latching arrangement 40. The latching arrangement 40 comprises a magnetic retaining member 42 associated with each output optical fibre 36. A magnetically responsive latching element 44 is carried proximate a free end of the cantilevered combination of the transducer 16 and the input optical fibre 12. The retaining members 42 are permanent magnets.

As shown in FIG. 9 of the drawings, initially the optical fibre 12 is held in alignment with the upper output optical fibre 36 due to the latching element 44 being magnetically held by the upper retaining member 42. The transducer 16 is in its rest condition due to its electrodes 22, 26 not being energised.

When it is desired to switch the optical fibre conduit 12 into alignment with the lower output optical fibre 36, the electrodes 22, 26, as the case may be, of the transducer 16 are energised to cause deflection of the sleeve 18 in the direction or arrow 46. This urges the latching element 42 out of engagement with the upper retaining member 42. When the free end of the sleeve 18 of the transducer 16 reaches its maximum arc of travel, the latching element 44 is magnetically held by the lower magnetic retaining member 42 so that the input optical fibre 12 is now in alignment with the lower output optical fibre 36. The supply of energy to the electrodes 22, 26 of the transducer 16 is discontinued so that the sleeve 18 again adopts its rest condition.

It is an advantage of this embodiment that the need to continuously maintain a supply of voltage to the transducer 16 is obviated.

It is a particular advantage of the invention that the need for mechanically operated switching devices is obviated thereby improving the efficiency and carrying capacity of an optical fibre network. In addition, the cost of the switch 10 is lower than an equivalent mechanical device and has reduced energy losses in comparison with a mechanical device.

In addition, the applicant is of the view that with the developments occurring in optical computer systems the switch 10 will find ready application in such computer systems to provide faster and smaller systems.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. An optical fibre switch which includes:
an optical fibre conduit;
a transducer carried on the conduit, the transducer converting input energy of one form into mechanical energy so that the application of an external stimulus causes a change in condition of the transducer which imparts that change in condition to the conduit; and
an input energy applying arrangement arranged on the transducer for applying the external stimulus.

2. The switch of claim 1 in which the optical fibre conduit is a single optical fibre having a single conduit for guiding a light beam.

3. The switch of claim 1 in which the optical fibre conduit is a conduit containing a bundle of optical fibres.

4. The switch of claim 1 in which the transducer converts input electrical energy into mechanical energy.

5. The switch of claim 4 in which the transducer comprises dielectric crystals that undergo mechanical stress upon the application of a voltage to the crystals.

6. The switch of claim 5 in which the transducer is a sleeve of a piezoelectric material which, when the external stimulus is applied to the sleeve, causes a change in the mechanical condition of the sleeve.

7. The switch of claim 6 in which the input energy applying arrangement is in the form of an electrode assembly carried on an external surface of the piezoelectric material.

8. The switch of claim 7 in which the electrode assembly comprises at least two pairs of opposed electrodes arranged on the coating for effecting bending of the conduit in the desired direction.

9. The switch of claim 7 in which the electrode assembly includes a ground electrode arranged on an operatively inner surface of the sleeve of piezoelectric material.

10. The switch of claim 6 in which the piezoelectric material is a piezoelectric ceramic material having a high electromechanical coupling coefficient.

11. The switch of claim 10 in which the piezoelectric ceramic material is lead zirconate titanate (PZT).

12. The switch of claim 6 in which the sleeve is formed by a deposition technique.

13. The switch of claim 12 in which the sleeve is formed by an electrophoretic deposition technique on a former, the former subsequently being removed.

14. The switch of claim 1 further including a housing in which the transducer and the optical fibre conduit are arranged.

15. The switch of claim 14 in which a combination of the transducer with the optical fibre conduit therein is mounted in a cantilevered arrangement in the housing.

16. The switch of claim 14 further including a latching arrangement for latching at least the optical fibre conduit in a desired position in the housing.

17. The switch of claim 16 in which the latching arrangement comprises a latching element carried proximate a free end of the cantilevered combination and at least one retaining member arranged in the housing to hold at least the optical fibre conduit in its switched position.

18. The switch of claim 17 in which the at least one retaining member is a magnetic device and the latching element comprises a magnetically responsive element carried by the cantilevered arrangement.

19. The switch of claim 1 in which the transducer is a snug fit over the optical fibre conduit.

20. The switch of claim 1 in which the transducer is a rattling fit over the optical fibre conduit.

21. A switch transducer which includes
a sleeve of a piezoelectric material; and
an input energy applying arrangement arranged on the sleeve for applying an external stimulus to the sleeve.

22. The transducer of claim 21 in which the piezoelectric material is a piezoelectric ceramic material having a high electromechanical coupling coefficient.

23. The transducer of claim 22 in which the piezoelectric ceramic material is lead zirconate titanate (PZT).

24. The transducer of a claim 21 in which the sleeve is formed by a deposition technique.

25. The transducer of claim 24 in which the sleeve is formed by an electrophoretic deposition technique on a former, the former subsequently being removed.

26. The transducer of claim 21 in which the input energy applying arrangement is in the form of an electrode assembly carried on an external surface of the piezoelectric material.

27. The transducer of claim 26 in which the electrode assembly comprises at least two pairs of opposed electrodes arranged on the coating for effecting bending of the conduit in the desired direction.

28. The transducer of claim 26 in which the electrode assembly includes a ground electrode arranged on an operatively inner surface of the sleeve of piezoelectric material.
